(19) United States
(12) Patent Application Publication
(10) Pub. No.: US 2012/0039045 A1
(43) Pub. Date: Feb. 16, 2012

(54) POWER MODULE AND METHOD FOR DETECTING INSULATION DEGRADATION THEREOF

(75) Inventors: Xiaohong Yin, Tokyo (JP); Takashi Nishimura, Tokyo (JP); Kei Yamamoto, Tokyo (JP); Kazuhiro Tada, Tokyo (JP); Tatsuya Okuda, Tokyo (JP); Takeshi Oi, Tokyo (JP)

(73) Assignee: MITSUBISHI ELECTRIC CORPORATION, Tokyo (JP)

(21) Appl. No.: 13/265,446

(22) PCT Filed: Apr. 1, 2010
(86) PCT No.: PCT/JP2010/056017

§ 371 Date: Oct. 20, 2011

(30) Foreign Application Priority Data
Apr. 22, 2009 (JP) 2009-104140

(51) Int. Cl. H05K 7/20

(52) U.S. Cl. 361/713

(57) ABSTRACT

A method and device for detecting insulation degradation of a power module, which detects, in advance, degradation of an insulating sheet based on a current change immediately before breakdown of an insulation characteristic from a current value of a current flowing through the insulating sheet, thereby detecting a failure of a power module caused by the degradation of insulation. The device includes: a current detector sampling and detecting a current value of a current flowing through an insulating sheet of the power module at a predetermined time interval; a calculator determining, based on the current value, a state in which the insulation characteristic of the insulating sheet is so degraded that the breakdown is imminent, and outputting a degradation determination result of YES when it is determined that the insulating sheet is in the state immediately before the breakdown; a current storage storing a current value i(n−1) at a previous sampling time point; and an alarm generating an alarm in response to the degradation determination result of YES. The calculator outputs the degradation determination result of YES when a present current value in exceeds ten times the previous current value i(n−1).

### TECHNICAL FIELD

The present invention relates to a method and a device for detecting insulation degradation of a power module, which are used for the power module including an insulating resin layer (insulating sheet) and are capable of detecting degradation of the insulating sheet caused by high temperature and moisture absorption. The present invention also relates to a power module system.

### BACKGROUND ART

It has conventionally been required for a power module to efficiently emit heat generated from a power semiconductor chip while electrical insulation is secured.

A general power module is constructed by fixing a ceramic substrate or a metal core substrate, on which circuit wiring is formed, and which carries a power semiconductor device, to a frame case made of a thermoplastic resin, filling the frame case with a silicone gel or an epoxy resin, and sealing the entirety thereof.

However, it is known that the power module of this type is high in manufacturing cost.

Therefore, a power module, which uses a lead frame and is transfer-molded by a sealing resin, has been developed in order to reduce the manufacturing cost (refer to Patent Literature 1, for example).

It is known that this type of transfer molding is excellent in productivity, thereby reducing the manufacturing cost, and has high reliability in the heat cycle characteristic, the power cycle characteristic, and the like because the entirety is covered with the resin having a high elastic modulus, which is different from the silicone gel.

On the other hand, the power module is often used in an environment having a high temperature and a high humidity while a high voltage is applied, and hence the power module possibly fails due to degradation of the insulating sheet. Accordingly, it is necessary to take some measures.

In the above-mentioned Patent Literature 1, in order to improve the heat discharge characteristic, a circuit board and a package for resin molding in which a lead frame is provided on a metal plate while an insulation layer is interposed therebetween is proposed for household and industrial modules, and an inexpensive power module excellent in heat discharge characteristic from the semiconductor chip to the metal plate is realized by resin sealing of carrying out transfer molding once.

### CITATION LIST

### Patent Literature

PTL 1: JP 2001-196495 A

### SUMMARY OF INVENTION

### Technical Problem

However, according to the conventional technology described above, considering an actual environment in which a power module is used, there is a problem in that the power module is often used under influence of a high temperature, a high humidity, and vibrations, and materials based on an organic epoxy resin especially absorb humidity in a high-temperature/high-humidity environment, resulting in a degradation of an insulation characteristic.

Moreover, in a power module operating at a high voltage, it is important to maintain the insulation characteristic thereof. However, the power module described in Patent Literature 1 is used in a high-temperature/high-humidity environment while a high voltage is applied between the metal plate and the lead frame, and thus there is a problem that the insulation can become defective as a result of degradation of the insulating layer as the operation time increases.

Particularly, in recent years, power modules are often used for onboard vehicle application, and a failure of the power module leads to a serious problem depending on the case. Hence, a certain failsafe design is preferably employed, but a particular countermeasure has not been realized yet.

The present invention has been made in view of the above-mentioned problems, and therefore has an object to provide a method and device for detecting insulation degradation of a power module which enable failsafe control by, in a transfer-mold type power module having an insulating sheet structure employing an epoxy resin as a sealing material or a case type power module employing a silicone gel (or an epoxy resin) as a sealing material, detecting, before an insulation characteristic of an insulating layer (insulating sheet) is degraded to breakdown, a characteristic change of a current value of a current flowing through the insulating sheet, and reporting the insulation abnormality before the power module fails in response to the detection result.

### Solution to Problem

According to the present invention, there is provided a device for detecting insulation degradation of a power module, including: current detection means for sampling and detecting a current value of a current flowing through an insulating sheet of the power module at a predetermined time interval; calculation means for determining, based on the current value, a state in which an insulation characteristic of the insulating sheet is so degraded that breakdown is imminent, and outputting a degradation determination result when the calculation means determines that the insulating sheet is in the state immediately before the breakdown; current storage means for storing a current value at a previous sampling time point; and alarm means for generating an alarm in response to the degradation determination result, in which the calculation means outputs the degradation determination result when a current value at a present sampling time point exceeds ten times the current value at the previous sampling time point.

### Advantageous Effects of Invention

According to the present invention, in a power module having the insulating sheet structure employing an epoxy resin as the sealing material, the degradation of the insulating sheet can be detected in advance by detecting the current value of the current flowing through the insulating sheet, and instability resulting from a failure of the power module caused by the insulation degradation of the insulating sheet can thus be prevented. As a result, the remarkable operation/effect which cannot be realized by the conventional technology can be provided.

### BRIEF DESCRIPTION OF DRAWINGS

FIG. 1 A cross sectional view schematically illustrating a structure of a transfer-mold type power module to which a first embodiment of the present invention is applied (first embodiment).

FIG. 2 A cross sectional view schematically illustrating a structure of a case type power module to which the first embodiment of the present invention is applied (first embodiment).

FIG. 3 A block diagram illustrating a device for detecting insulation degradation of a power module according to the first embodiment of the present invention (first embodiment).

FIG. 4 An explanatory diagram illustrating a temporal change in a current value of a current flowing through an insulating sheet in a high-temperature/high-humidity environment (85° C./85% RH) (first embodiment).

FIG. 5 An explanatory diagram illustrating a temporal change in a current value immediately before breakdown of the insulating sheet in the high-temperature/high-humidity environment (85° C./85% RH) (first embodiment).

FIG. 6 A block diagram illustrating the device for detecting insulation degradation of a power module according to the first embodiment of the present invention (first embodiment).

FIG. 7 A block diagram illustrating a device for detecting insulation degradation of a power module according to a second embodiment of the present invention (second embodiment).

FIG. 8 An explanatory diagram illustrating a temporal change (measurement example) in a differentiated value of the current value immediately before breakdown of the insulating sheet in the high-temperature/high-humidity environment (85° C./85% RH) according to the second embodiment of the present invention (second embodiment).

FIG. 9 A cross sectional view schematically illustrating a power module unit of a power module system according to a third embodiment of the present invention (third embodiment).

FIG. 10 A block diagram illustrating the power module system according to the third embodiment of the present invention (third embodiment).

FIG. 11 Timing charts illustrating a voltage signal and an electromagnetic signal for a case in which insulation degradation is not generated and a case in which insulation degradation is generated in the power module of FIG. 10 (third embodiment).

FIG. 12 A block diagram illustrating a power module system according to a fourth embodiment of the present invention (fourth embodiment).

FIG. 13 A timing chart illustrating the electromagnetic signal after a switching signal is removed according to the fourth embodiment of the present invention (fourth embodiment).

FIG. 14 A block diagram illustrating a device for detecting insulation degradation of a power module according to a fifth embodiment of the present invention (fifth embodiment).

FIG. 15 Timing charts illustrating a relationship between a voltage signal applied to a main circuit and a current signal detected by high-speed current detection means for a case in which insulation degradation is not generated and a case in which insulation degradation is generated in the power module of FIG. 14 (fifth embodiment).

FIG. 16 A timing chart illustrating a relationship between a current signal from the high-speed current detection means and a current signal after passing through signal processing means according to the fifth embodiment of the present invention (fifth embodiment).

FIG. 17 A block diagram illustrating a device for detecting insulation degradation of a power module according to a sixth embodiment of the present invention (sixth embodiment).

FIG. 18 Timing charts illustrating a current signal extraction method corresponding to a method for detecting insulation degradation according to the sixth embodiment of the present invention (sixth embodiment).

### DESCRIPTION OF EMBODIMENTS

### First Embodiment

A detailed description is now given of a first embodiment of the present invention with reference to the drawings.

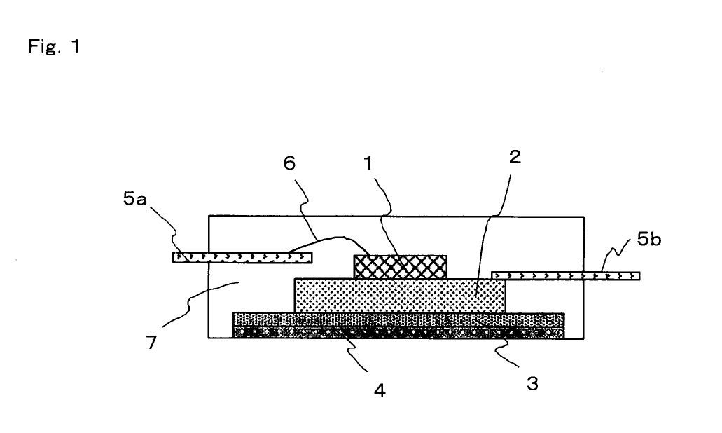

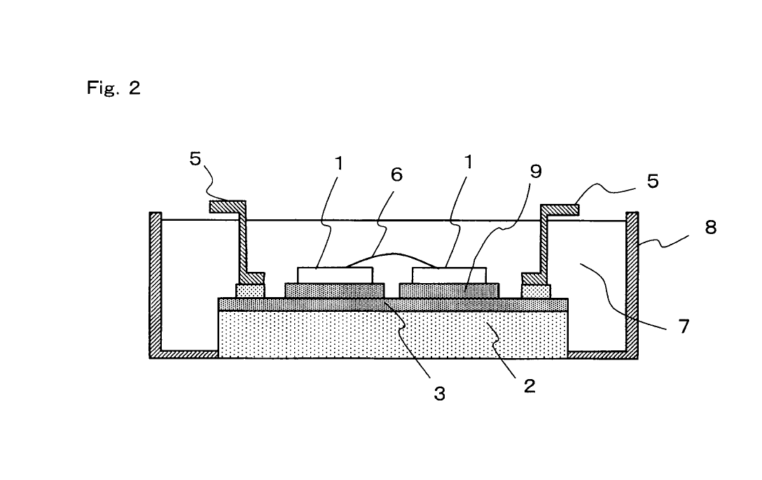

A description is first given of a power module having an insulating sheet structure to which the first embodiment of the present invention is applied. FIGS. 1 and 2 are cross sectional views schematically illustrating a structure of a power module. FIG. 1 illustrates a transfer-mold type power module and FIG. 2 illustrates a case type power module.

In FIG. 1, the transfer-mold type power module includes a semiconductor chip 1, a heat spreader 2, an insulating sheet 3, a copper foil 4, lead frames 5a and 5b, a bonding wire 6, and an epoxy resin 7.

The semiconductor chip 1 is mounted on the heat spreader 2, and the copper foil 4 is in close contact with a rear surface of the heat spreader 2 through the intermediation of the insulating sheet 3. The insulating sheet 3 is disposed between the heat spreader 2 and the copper foil 4 in close contact with each other.

The lead frame 5a is connected to the semiconductor chip 1 via the bonding wire 6, and the lead frame 5b is directly connected to the heat spreader 2.

All the components mentioned above are encapsulated using the epoxy resin 7 by means of the transfer molding method.

With the construction of FIG. 1, heat generated from the semiconductor chip 1 is discharged to the outside via the heat spreader 2, the insulating sheet 3, and the copper foil 4.

In FIG. 2, the case type power module includes semiconductor chips 1, a heat spreader 2, an insulating sheet 3, terminals 5, a bonding wire 6, an epoxy resin (or silicone gel) 7 for sealing, a case 8 made of a thermoplastic resin, and a copper wiring board 9.

The copper wiring board 9 is placed on the heat spreader 2 through the intermediation of the insulating sheet 3, the semiconductor chips 1 are mounted on the copper wiring board 9, and the terminals 5 are connected thereto.

The insulating sheet 3 is placed between the copper wiring board 9 on which the semiconductor chips 1 are mounted and the heat spreader 2 in close contact therewith.

With the construction of FIG. 2, heat generated from the semiconductor chips 1 is discharged to the outside via the copper wiring board 9, the insulating sheet 3, and the heat spreader 2.

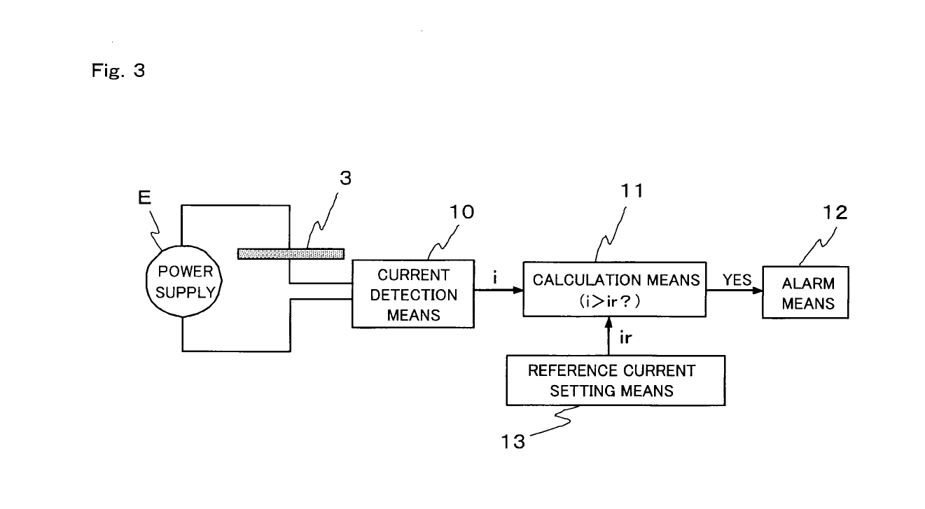

FIG. 3 is a functional block diagram illustrating a device for detecting insulation degradation of a power module according to the present invention, and illustrates a configuration example for a case in which insulation degradation of the insulating sheet 3 is detected while a current value (change in current value) of a current flowing through the insulating sheet 3 in FIG. 1 or 2 is considered as a degradation determination index.

In FIG. 3, the device for detecting insulation degradation of a power module includes a power supply E for supplying the insulating sheet 3 with power, current detection means 10 for sampling and detecting a current value i flowing through the insulating sheet 3 at a predetermined time interval, calculation means 11 including a degradation determination function based on the current value i (detected value), alarm means 12 for carrying out alarm drive in response to a degradation determination result of YES from the calculation means 11, and reference current setting means 13 for setting a reference current ir used for the degradation determination by the calculation means 11.

The current detection means 10 detects the current value i of the current flowing through the insulating sheet 3 via the lead frame 5b and the copper foil 4 of FIG. 1 (or via the terminals 5 and the heat spreader 2 of FIG. 2).

The calculation means 11 carries out comparison between the current value i detected by the current detection means 10 and the reference current ir set by the reference current setting means 13, and outputs the degradation determination result of YES to the alarm means 12 when a relationship of i>ir is satisfied.

Note that, the current value i is sampled at the predetermined time interval in the current detection means 10, and the calculation means 11 outputs the degradation determination result of YES when the current value i at the sampling time point exceeds the reference current ir corresponding to a current value immediately before breakdown of the insulating sheet.

The alarm means 12 reports the state in which the power module is immediately before a failure (a few minutes to a few tens of hours to occurrence of a failure) by means of an audio drive or light emission in response to the degradation determination result of YES.

Note that, the reference current ir set by the reference current setting means 13 is set to a current value slightly smaller than a current value corresponding to the insulation degradation of the insulating sheet 3. Moreover, though the reference current ir may be acquired in advance from an experimental result, the reference current ir may be arbitrarily set according to the voltage applied to the insulating sheet 3 or a material or the thickness of the insulating sheet 3.

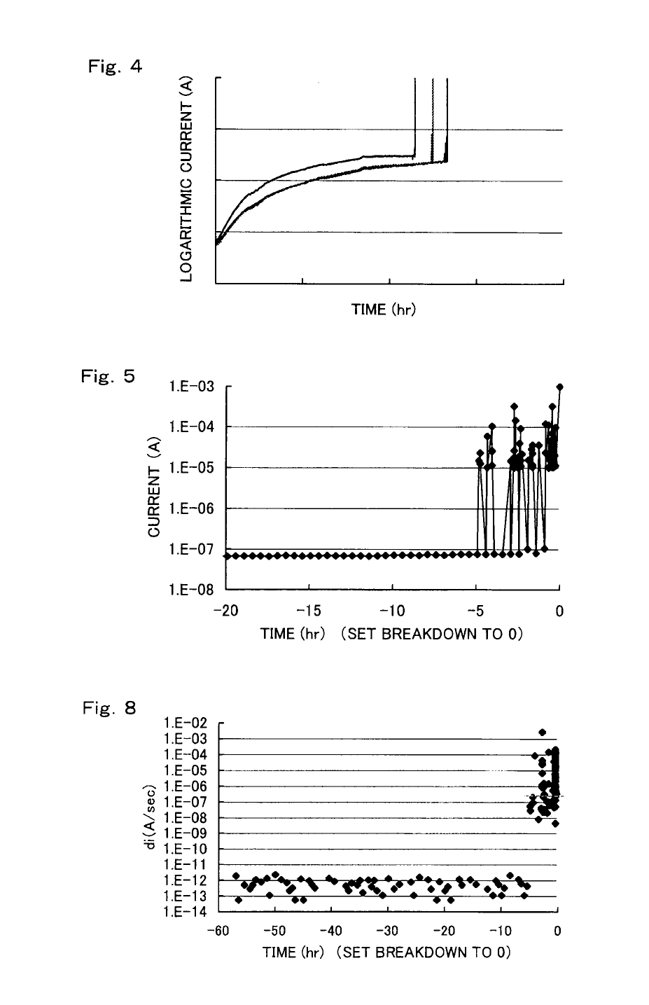

A description is now given of an operation principle illustrated in FIG. 3 with reference to explanatory diagrams of FIGS. 4 and 5.

As described above, the power module is generally exposed to a high-temperature/high-humidity environment, and if the power module is used for a long period in the high-temperature/high-humidity environment, the insulating sheet 3, which has absorbed moisture, degrades in terms of electrical characteristics, mechanical characteristics, and thermal characteristics, and the insulation degradation can finally cause defective insulation.

FIG. 4 is an explanatory diagram illustrating a temporal change of the current value i (logarithmic current) [A] of the current flowing through the insulating sheet 3, and each of measurement examples for cases in which a high voltage is applied to three power modules in the high-temperature/high-humidity environment (85° C./85% RH).

As is apparent from FIG. 4, it can be understood that though the current value i of the current flowing through the insulating sheet 3 gradually increases as a period of absorbing humidity extends in a certain time area up to a long dashed short dashed line, the current value i drastically increases after the certain time. This means breakdown of the insulating sheet 3.

Moreover, though the insulation breakdown periods are different due to a variation among the respective three power modules, it can also be understood that the changes in the current value immediately before the breakdown of the insulating sheet 3 are steep.

We could recognize in detail the change in the current value immediately before the breakdown of the insulating sheet 3 by shortening the sampling interval for the current value to thereby record the current value at a high speed.

FIG. 5 is an explanatory diagram illustrating a measurement example of the current value immediately before the breakdown of the insulating sheet 3, and a time of the breakdown is set to “0” on the time axis (horizontal axis).

In FIG. 5, when the current value exceeds a predetermined threshold set in advance, the sampling interval is set to a short period equal to or less than 40 ms.

As is apparent from FIG. 5, it can be understood that the insulating sheet 3 does not break down without a precursor, and that a momentary fluctuation of the current value repeats in a certain period over approximately five hours before the breakdown. In other words, it can be understood that the current pulse can be detected several times or more immediately before the insulating sheet 3 breaks down.

It is also confirmed that the period from a time point of the appearance of the phenomenon in which the current flowing through the insulating sheet 3 drastically increases by one digit (ten times) to the insulation breakdown of the insulating sheet 3 takes a few minutes to a few tens of hours according to an experimental result.

In other words, the precursory period until the insulation breakdown is an insulation degradation period in which the insulating sheet 3 reaches the insulation breakdown, and it can be understood that the insulation degradation before the breakdown of the insulating sheet 3 can be detected based on the characteristic of the current change immediately before the insulation breakdown.

Specifically, the calculation means 11 of FIG. 3 detects a timing at which the current value i detected by the current detection means 10 increases drastically, considers the timing of the current increase as an indicator for the degradation determination of the insulating sheet 3, detects beforehand a failure of the power module caused by the insulation degradation of the insulating sheet 3, and drives the alarm means 12.

As described above, the device for detecting insulation degradation of a power module of FIG. 3 includes the current detection means 10 for sampling and detecting the current value i of the current flowing through the insulating sheet 3 of the power module at the predetermined time interval, the calculation means 11 for determining, based on the current value i, the state in which the insulation characteristic of the insulating sheet 3 is so degraded that the breakdown is imminent, and outputting the degradation determination result of YES when it is determined that the insulating sheet 3 is in the state immediately before breakdown, and the alarm means 12 for generating the alarm in response to the degradation determination result of YES.

Moreover, the current i is sampled at the predetermined time interval, and the calculation means 11 outputs the degradation determination result of YES when the current value i at the sampling time point exceeds the reference current ir corresponding to the current value immediately before the breakdown of the insulating sheet 3. Therefore, the degradation of the insulating sheet 3 can be detected in advance.

Failsafe control is thus provided by detecting the characteristic change of the current value of the current flowing through the insulating sheet before the insulation characteristic of the insulating layer (insulating sheet) degrades to breakdown, and reporting the abnormality before the power module fails in response to the detection result.

In other words, the failure of the power module caused by the insulation degradation of the insulating sheet 3 can be detected beforehand, and can be addressed immediately before the failure.

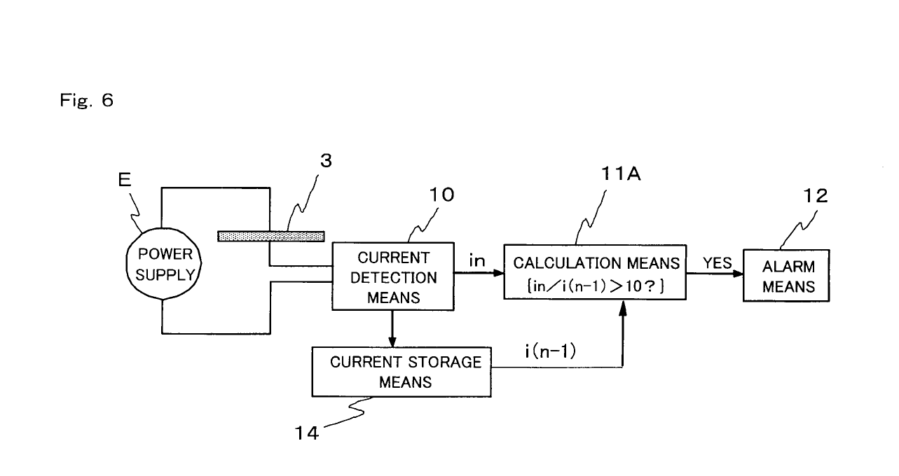

Though, in FIG. 3, the current value i at the sampling time point and the reference current ir are compared with each other in the calculation means 11, a current value in at the present sampling time point is preferably compared to a current value i(n−1) at a previous sampling time point in calculation means 11A as illustrated in FIG. 6.

FIG. 6 is a functional block diagram illustrating the device for detecting insulation degradation of a power module according to the first embodiment of the present invention. The like components are denoted by like symbols or by like symbols followed by “A” as those described above (refer to FIG. 3), and a detailed description thereof is therefore omitted.

In FIG. 6, current storage means 14 is provided in place of the reference current setting means 13 described above (FIG. 3).

The current storage means 14 stores the current value i(n−1) at the previous sampling time point, and inputs the previous current value i(n−1) to the calculation means 11A.

The calculation means 11A carries out comparison between the current value in at the present sampling time point from the current detection means 10 and the current value i(n−1) at the previous sampling time point from the current storage means 14, and outputs the degradation determination result of YES when the ratio therebetween exceeds ten to one, that is, “in/i(n−1)>10”.

The current detection means 10 always samples the current value i of the current flowing through the insulating sheet 3 at a predetermined sampling speed during the operation of the power module, and inputs the current value in for each sampling into the calculation means 11A and the current storage means 14.

The current storage means 14 stores the current value at each of the sampling time points from the current detection means 10, and always inputs the current value i(n−1) which is acquired one sampling period before the present sampling time point into the calculation means 11A.

As a result, the calculation means 11A can always compare the current value i(n−1) one sampling period before and the current value in sampled at the present time point with each other, and determines that the insulating sheet 3 is in the insulation degradation state and outputs the degradation determination result of YES (alarm signal) to the alarm means 12 only when the present current value in exceeds ten times the previous current value i(n−1).

As described above, the device for detecting insulation degradation of a power module according to the first embodiment (FIG. 6) of the present invention includes the current storage means 14 for storing the current value at the previous sampling time point, and the calculation means 11A outputs the degradation determination result of “YES” when the current value in at the present sampling time point exceeds ten times the current value i (n−1) at the previous sampling time point.

As a result, as described above, the degradation of the insulating sheet 3 can be detected in advance, and a failure of the power module caused by the insulation degradation of the insulating sheet 3 can be detected beforehand.

Moreover, a method of detecting insulation degradation of a power module which provides similar operation/effect can be realized by replacing each of the means 10, 11A, 12, and 14 in FIG. 6 by a processing step.

### Second Embodiment

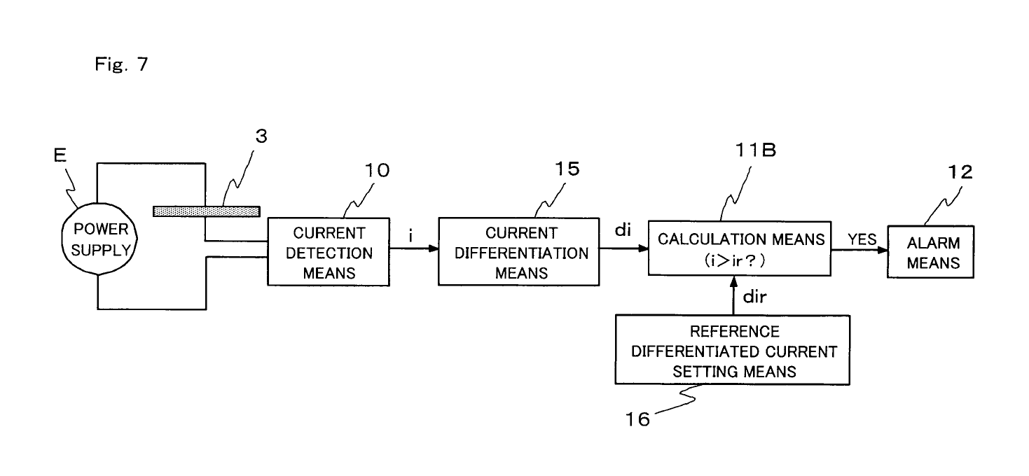

Though the current value in at the present sampling time point and the current value i(n−1) at the previous sampling time point are compared with each other in the calculation means 11A according to the first embodiment (FIG. 6) described above, a differentiated current di obtained by differentiating the current value i with respect to time (di/dt) at the sampling time point and a reference differentiated current dir may be compared with each other in calculation means 11B as illustrated in FIG. 7.

FIG. 6 is a functional block diagram illustrating a device for detecting insulation degradation of a power module according to a second embodiment of the present invention, the like components are denoted by like symbols or by like symbols followed by “B” as those described above (refer to FIG. 3), and a detailed description thereof is therefore omitted.

In FIG. 7, the device for detecting insulation degradation of a power module includes current differentiation means 15 for calculating the differentiated current di by differentiating the current value i between the current detection means 10 and the calculation means 11B, and a reference differentiated current setting means 16 for setting the reference differentiated current dir serving as the determination reference value in place of the reference current setting means 13 described above (FIG. 3).

In this case, the current detection means 10 inputs the current value i to the current differentiation means 15, and the differentiated current di is input to the calculation means 11B.

When the differentiated current di of the current value i at the sampling time point exceeds the reference differentiated current dir, the calculation means 11B outputs the degradation determination result of YES, thereby driving the alarm means 12.

Specifically, during the operation of the power module, the current detection means 10 detects the current value i of the current flowing through the insulating sheet 3, and inputs the current value i to the current differentiation means 15, and the current differentiation means 15 calculates the differentiated current di and inputs the differentiated current di to the calculation means 11B.

The calculation means 11B compares the differentiated current di and the reference differentiated current dir, and outputs the degradation determination result of YES (alarm signal) to the alarm means 12 only when the relationship “di>dir” is satisfied and the differentiated current di thus exceeds the reference differentiated current dir.

Though the reference differentiated current dir varies depending on the voltage applied to the insulating sheet 3 and the material of the insulating sheet 3, the reference differentiated current dir may generally be set to 10⁻¹¹ [A/sec] or larger as illustrated in FIG. 8, for example.

FIG. 8 is an explanatory diagram illustrating a temporal change (measurement example) in the differentiated value of the current value i immediately before the breakdown of the insulating sheet in the high-temperature/high-humidity environment (85° C./85% RH) according to the second embodiment of the present invention.

According to the above-mentioned experimental result (FIG. 5), the current value i repeats the increase and the recovery in the insulation degradation period immediately before the insulation breakdown of the insulating sheet 3, and one fluctuation (increase) in the current value i occurs in the extremely short period. Therefore, the sudden fluctuation in the current value i generated in the insulation degradation period can be easily detected as the differentiated current di.

As described above, the device for detecting insulation degradation of a power module according to the second embodiment of the present invention includes the current differentiation means 15 for calculating the differentiated current di of the current value i detected by the current detection means 10, and the calculation means 11B outputs the degradation determination result of YES when the differentiated current di of the current value i at the sampling time point exceeds the reference differentiated current dir. Therefore, the degradation of the insulating sheet 3 can be detected in advance as described above, and a failure of the power module caused by the insulation degradation of the insulating sheet 3 can be detected.

Moreover, a method of detecting insulation degradation of a power module which provides similar operation/effect can be realized by replacing each of the means 10, 11B, 12, 15, and 16 in FIG. 7 by a processing step.

### Third Embodiment

While the devices (and methods) for detecting insulation degradation of a power module are described in the first and second embodiments (FIGS. 6 and 7) described above, the above-mentioned device for detecting insulation degradation of a power module may be used to construct a power module system.

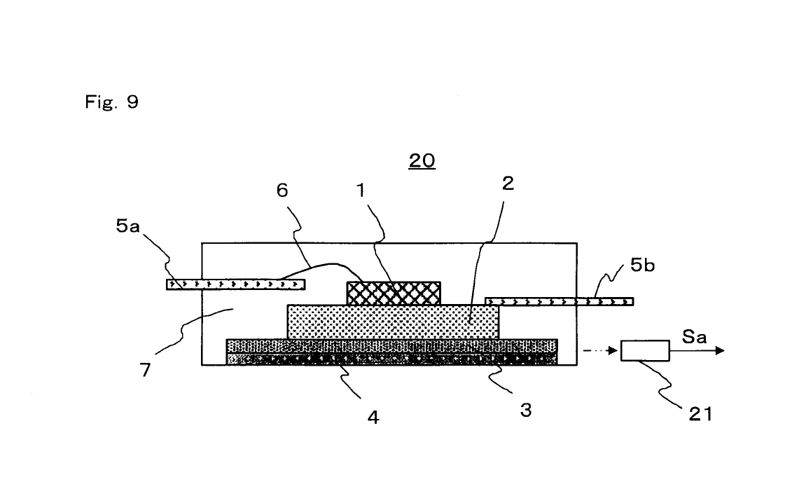

FIG. 9 is a cross sectional view schematically illustrating a power module unit of the power module system according to a third embodiment of the present invention. The like components are denoted by like symbols as those described above (refer to FIG. 1), and a detailed description thereof is therefore omitted.

In FIG. 9, an antenna 21 is disposed in place of the current detection means 10 described above (FIGS. 3, 6, and 7) in a neighborhood of a power module 20.

The antenna 21 detects a change in the current of the insulating sheet 3 by detecting an electromagnetic wave emitted from the power module 20 as an electromagnetic wave signal Sa.

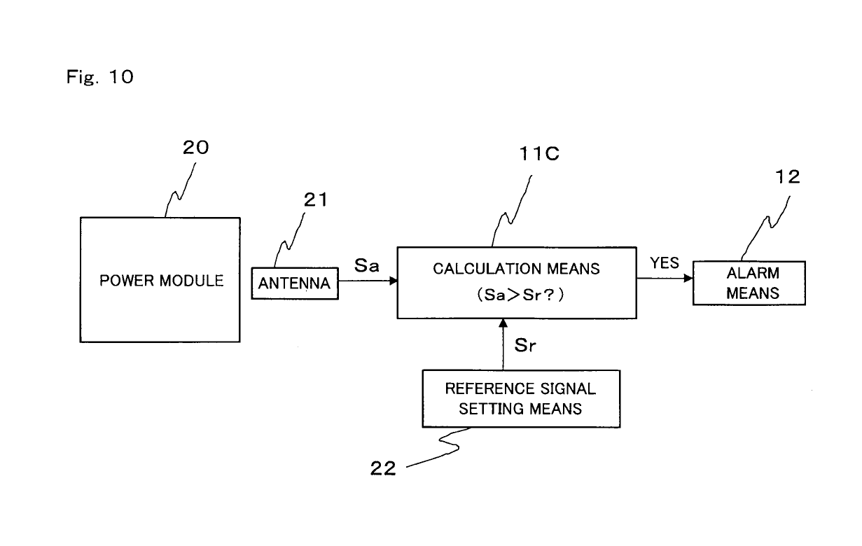

FIG. 10 is a block diagram illustrating the power module system according to the third embodiment of the present invention. The like components are denoted by like symbols or by like symbols followed by “C” as those described above (refer to FIGS. 3, 6, and 7), and a detailed description thereof is therefore omitted.

In FIG. 10, the power module system includes the power module 20, the antenna 21, calculation means 11C receiving an input of the electromagnetic wave signal Sa from the antenna 21, the alarm means 12 to be driven by the degradation determination result of YES from the calculation means 11C, and the reference signal setting means 22 for setting a reference signal Sr serving as a degradation determination reference value in the calculation means 11C.

The calculation means 11C carries out arithmetic processing using the electromagnetic signal Sa from the antenna 21 and the reference signal Sr from the reference signal setting means 22 as input information, and outputs the degradation determination result of YES to the alarm means 12 when the insulation degradation is determined.

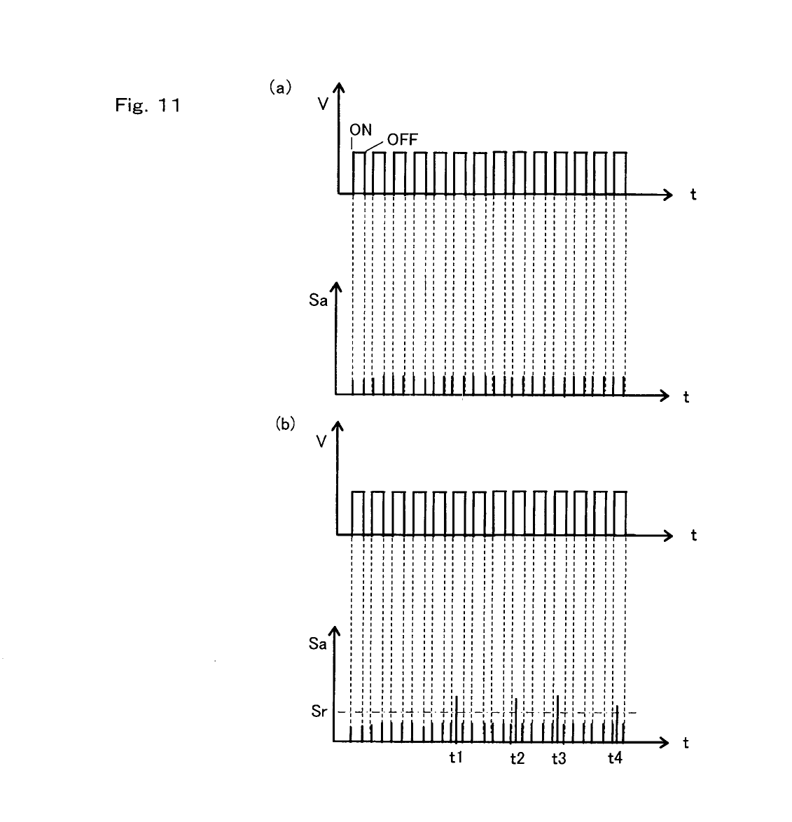

A description is now given of an operation of the third embodiment of the present invention illustrated in FIGS. 9 and 10 with reference to FIG. 11 along with the above-mentioned FIG. 5.

As illustrated in FIG. 5, in the period immediately before the breakdown of the insulating sheet 3, the increase and the recovery of the current value i are repeated. Though one current fluctuation (increase) occurs in the short period, the sudden fluctuation in the current value i generated in the insulation degradation period appears as a current pulse, and an electromagnetic wave is emitted at the same time.

The electromagnetic wave generated by the sudden fluctuation of the current value i in the power module 20 is detected by the antenna 21, and is input as the electromagnetic wave signal Sa to the calculation means 11C.

However, a voltage V always changes in the actual power module 20 due to switching on/off, and noises are generated by the voltage change. Thus, the noises due to the voltage change are detected by the antenna 21.

FIGS. 11(a) and 11(b) are timing charts illustrating a relationship between the voltage signal V and the electromagnetic signal Sa, FIG. 11(a) illustrates a temporal fluctuation of the electromagnetic wave signal Sa when the voltage is turned on/off in a case where the insulating sheet 3 is not degraded, and FIG. 11(b) illustrates a temporal fluctuation of the electromagnetic wave signal Sa when the voltage is turned on/off in a case where the insulating sheet 3 is degraded.

In FIG. 11(a), the applied voltage V of the power module 20 changes drastically when the voltage is turned on and off, and a noise signal caused by the drastic change is detected as the electromagnetic signal Sa by the antenna 21.

On the other hand, the electromagnetic wave signal Sa in FIG. 11(b) presents pulse signals at a high level at times t1, t2, t3, and t4 in addition to the noise signal corresponding to the turning on/off of the voltage V. This corresponds to the drastic change of the current generated by the degradation of the insulating sheet 3, and represents the precursor of the failure of the power module 20.

As illustrated in FIG. 11(b), the electromagnetic signal Sa contains the noise signal generated by the drastic change of the voltage V in addition to the signals generated by the degradation of the insulating sheet 3, and it is thus necessary to extract only the signals generated by the degradation of the insulating sheet 3 from the electromagnetic signal Sa in order to detect the failure of the power module 20.

Therefore, as illustrated in FIG. 10, the calculation means 11C extracts only the high level signals generated by the degradation using the reference signal Sr as a threshold.

While when the degradation occurs in the insulating sheet 3, the high level electromagnetic signal Sa is generally detected in the antenna 21, the noise signal generated by the drastic change in the voltage V is at a low level as illustrated in FIG. 11.

The electromagnetic signal Sa and the noise signal can be discriminated from each other by setting the threshold level between the electromagnetic signal Sa at the time of occurrence of the insulation degradation and the noise signal.

The threshold level in this case corresponds to the reference signal Sr set by the reference signal setting means 22.

Specifically, the calculation means 11C receives the electromagnetic wave signal Sa detected by the antenna 21 and the reference signal Sr set by the reference signal setting means 22 as input information, carries out the comparison therebetween, and outputs the degradation determination result of YES indicating that the insulating sheet 3 is degraded to the alarm means 12 only when Sa>Sr is satisfied.

The alarm means 12, upon receiving the degradation determination result of YES (failure signal) from the calculation means 11C, prompts an operator to take countermeasures by generating an alarm indicating that the power module 20 is immediately (few minutes to few tens of hours) before the failure.

Though the reference signal Sr may be acquired from an experimental result in advance, the reference signal Sr may be arbitrarily set according to the applied voltage V of the power module 20.

As described above, the power module system according to the third embodiment (FIGS. 9 and 10) of the present invention includes the antenna 21 for detecting the electromagnetic wave signal Sa emitted from the power module 20, the reference signal setting means 22 for setting the reference signal Sr indicating the degradation of the insulating sheet 3, the alarm means 12 to be driven by the degradation determination result of YES, and the calculation means 11C for carrying out the comparison using the electromagnetic wave signal Sa and the reference signal Sr as the input information, and outputting the degradation determination result of YES to the alarm means 12 only when the electromagnetic signal Sa exceeds the reference signal Sr.

As a result, the degradation of the insulating sheet 3 can be detected in advance and a failure of the power module 20 caused by the insulation degradation of the insulating sheet 3 can be detected.

It is to be understood that though, in the above description, the alarm means 12 which has received the degradation determination result of YES from the calculation means 11C immediately generates the alarm, the alarm may be generated at a time point when a predetermined number of the degradation determination results of YES have been received within a predetermined period in order to avoid a malfunction by providing redundancy.

### Fourth Embodiment

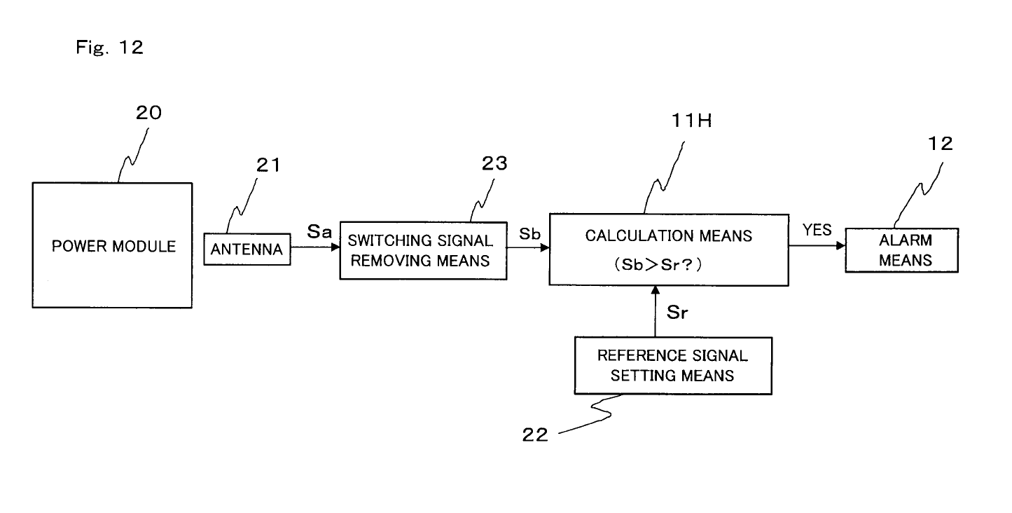

Though the degradation determination signal is generated by comparing the electromagnetic signal Sa and the reference signal Sr with each other in the calculation means 11C according to the third embodiment (FIG. 10) described above, as illustrated in FIG. 12, switching signal removing means 23 may be inserted between the antenna 21 and calculation means 11H.

FIG. 12 is a block diagram illustrating a power module system according to a fourth embodiment of the present invention, the like components are denoted by like symbols or by like symbols followed by “H” as those described above (refer to FIG. 10), and a detailed description thereof is therefore omitted.

In FIG. 12, the power module system includes the switching signal removing means 23 and the calculation means 11H in place of the above-mentioned calculation means 11C (FIG. 10).

The switching signal removing means 23 removes only the noise signal caused and generated by the turning on/off of the voltage V from the electromagnetic signal Sa input from the antenna 21, extracts only an electromagnetic signal Sb emitted at the time of the degradation of the insulating sheet 3, and inputs the electromagnetic signal Sb to the calculation means 11H.

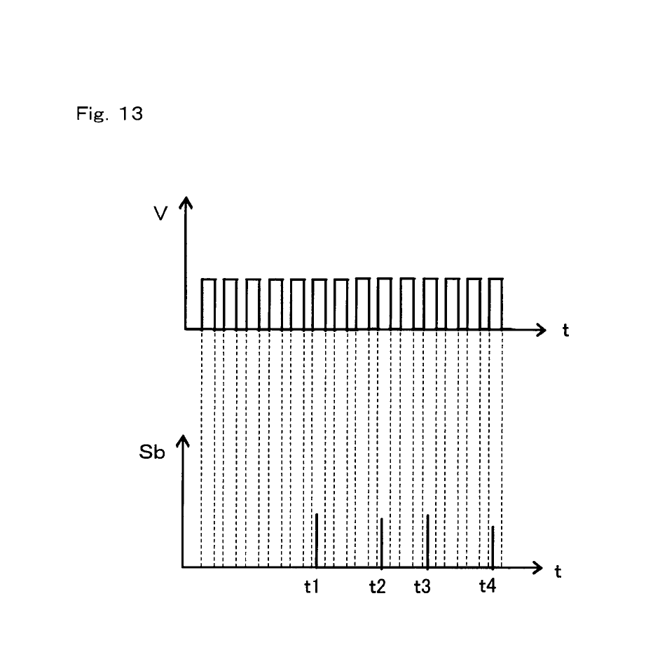

Referring to FIG. 13, a description is now given of an operation of the fourth embodiment of the present invention illustrated in FIG. 12.

First, the antenna 21 disposed close to the power module 20 detects the electromagnetic wave emitted from the power module 20 as described above, and inputs the detected electromagnetic wave as the electromagnetic wave signal Sa to the switching signal removing means 23.

The switching signal removing means 23 removes the signal (noise signal caused and generated by the turning on/off of the circuit voltage V) irrelevant to the degradation of the insulating sheet 3 from the electromagnetic wave signal Sa, and inputs only the electromagnetic signal Sb generated upon the failure of the insulating sheet 3 to the calculation means 11H.

FIG. 13 is a timing chart illustrating the electromagnetic signal Sb after the noise signal caused by the turning on/off of the voltage V is removed.

The calculation means 11H receives the electromagnetic wave signal Sb via the switching signal removing means 23 and the reference signal Sr set by the reference signal setting means 22 as input information, carries out the comparison therebetween, and outputs the degradation determination result of YES indicating that the insulating sheet 3 is degraded to the alarm means 12 only when Sb>Sr is satisfied.

Though the reference signal Sr may be acquired from an experimental result in advance, the reference signal Sr may be arbitrarily set according to the applied voltage V of the power module 20.

As described above, the power module system according to the fourth embodiment (FIG. 12) of the present invention includes the antenna 21 for detecting the electromagnetic signal Sa emitted from the power module 20, the switching signal removing means 23 for removing the noise signal caused and generated by the turning on/off of the circuit voltage V irrelevant to the degradation of the insulating sheet 3, the reference signal setting means 22, the alarm means 12 to be driven by the degradation determination result of YES, and the calculation means 11H for outputting the failure signal to the alarm means 12 only when the electromagnetic signal Sb from which the switching signal is removed exceeds the reference signal Sr.

As a result, the degradation of the insulating sheet 3 can be detected in advance and a failure of the power module 20 caused by the insulation degradation of the insulating sheet 3 can be detected.

It is to be understood that though, in the above description, the alarm means 12 which has received the degradation determination result of YES immediately generates the alarm, the alarm may be generated at a time point when a predetermined number of the degradation determination results of YES have been received within a predetermined period.

### Fifth Embodiment

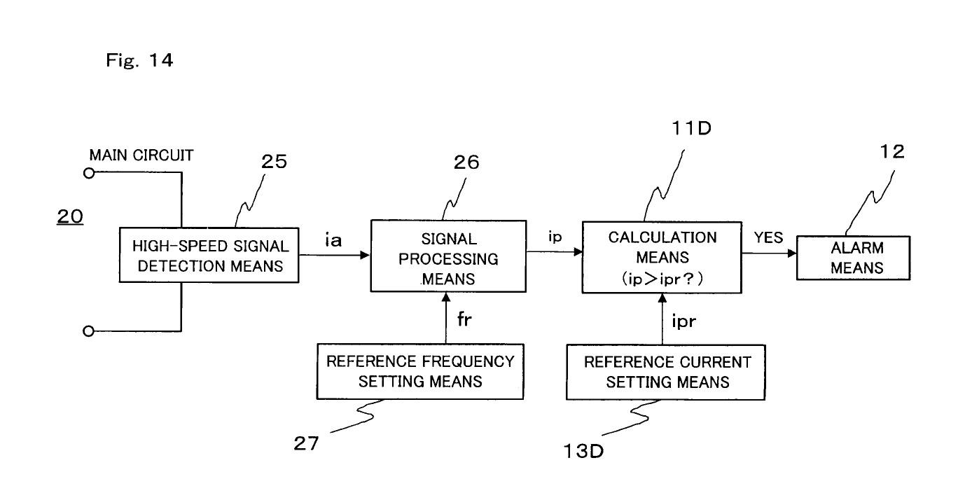

Though the current detection means 10 is used for detecting the current value i of the current flowing through the insulating sheet 3 according to the first and second embodiments (FIGS. 6 and 7) described above, high-speed current detection means 25 for detecting, at a high speed, a current signal is flowing through the main circuit of the power module 20 may be used as illustrated in FIG. 14.

FIG. 14 is a block diagram illustrating a device for detecting insulation degradation of a power module according to a fifth embodiment of the present invention, the like components are denoted by like symbols or by like symbols followed by “D” as those described above, and a detailed description thereof is therefore omitted. Further, the configuration of the power module 20 is as illustrated in FIG. 9.

In FIG. 14, the high-speed current detection means 25 is connected to the main circuit of the power module 20, and detects the current signal ia.

Signal processing means 26 carries out signal processing using the current signal ia from the high-speed current detection means 25 and a reference frequency fr set by reference frequency setting means 27 as input information, passes only a current signal ip (high frequency pulse signal) having a frequency equal to or higher than the reference frequency fr out of the current signal ia, and inputs the current signal ip to calculation means 11D.

The calculation means 11D carries out the arithmetic processing using the current signal ip via the signal processing means 26 and a reference current ipr set by reference current setting means 13D as input information, and inputs the degradation determination result of YES to the alarm means 12 only when the current signal ip exceeds the reference current ipr.

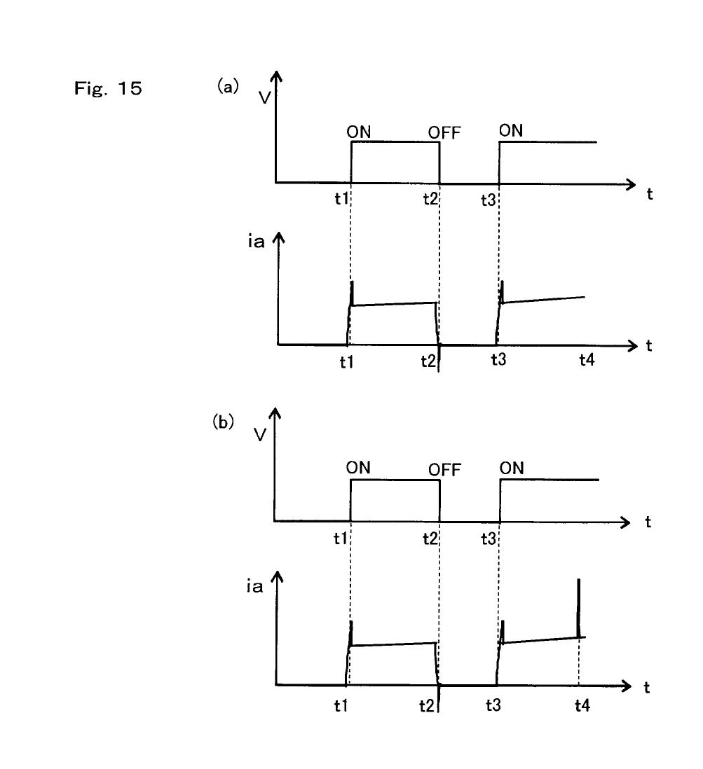

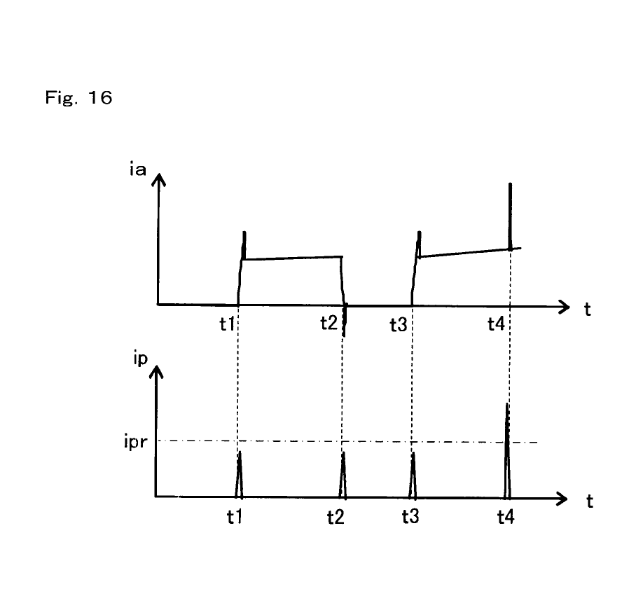

A description is now given of an operation of the fifth embodiment of the present invention illustrated in FIG. 14 with reference to FIGS. 15 and 16 along with the above-mentioned FIG. 5.

As described above (FIG. 5), in the period immediately before the breakdown of the insulating sheet 3, the increase and the recovery of the current signal ia are repeated. Note that, one fluctuation (increase) in the current signal ia occurs in an extremely short period, and hence the sudden fluctuation in the current signal ia generated in the insulation degradation period appears as a current pulse.

A sudden fluctuation of the current signal ia is detected by the high-speed current detection means 25 provided in the main circuit.

FIGS. 15(a) and 15(b) are timing charts illustrating a relationship between the voltage signal V applied to the main circuit and the current signal ia detected by the high-speed current detection means 25, FIG. 15(a) illustrates a temporal fluctuation of the current signal ia when the voltage is turned on/off in the case where the insulating sheet 3 is not degraded, and FIG. 15(b) illustrates a temporal fluctuation of the current signal ia when the voltage is turned on/off in the case where the insulating sheet 3 is degraded.

In FIG. 15(a), there are drastic changes in the applied voltage V at times t1 and t3 when the applied voltage V is turned on, and a time t2 when the applied voltage V is turned off, and the current signal ia which drastically changes at the times t1, t2, and t3 caused by these changes is detected by the high-speed current detection means 25.

In FIG. 15(b), the current signal ia contains, in addition to a signal corresponding to a rectangular signal caused by the turning on/off of the voltage, the noise signal corresponding to the drastic current changes at the respective times t1, t2, and t3, as well as a high level pulse signal generated at a time t4, for example. This corresponds to the drastic change of the current signal ia generated by the degradation of the insulating sheet 3, and represents the precursor of the failure of the power module 20 as described above.

FIG. 16 is a timing chart illustrating the input/output signals (current signals ia and ip) of the signal processing means 26, and illustrates a relationship between the current signal ia from the high-speed current detection means 25 and the current signal ip after passing through the signal processing means 26.

In FIG. 16, the current signal ip after passing through the signal processing means 26 contains only the high frequency pulse signal which is obtained by removing a low frequency component in the current signal ia.

As illustrated in FIG. 14, the signal processing means 26 provided on the subsequent stage of the high-speed current detection means 25 carries out processing so as to pass only the current signal ip (high frequency pulse signal) having a frequency equal to or higher than the reference frequency fr set by the reference frequency setting means 27 out of the current signal ia.

As a result, the current signal (high frequency pulse) corresponding to the degradation of the insulating sheet 3 and the current signal corresponding to the voltage switching of the main circuit of the power module 20 are extracted as the current signals ip containing the high frequency components.

As is apparent from FIG. 16, the level of the high frequency pulse caused by the insulation degradation is higher than the level of the pulse signal caused by the turning on/off of the voltage, and they are thus separated from each other by setting a threshold at an intermediate level thereof.

The calculation means 11D thus uses the reference current ipr set by the reference current setting means 13D as the threshold, thereby discriminating those current signals from each other.

Specifically, the calculation means 11D receives the current signal ip and the reference current ipr set by the reference current setting means 13D as input information, carries out the comparison therebetween, and outputs the degradation determination result of YES indicating that the insulating sheet 3 is degraded to the alarm means 12 only when ip>ipr is satisfied.

The alarm means 12, upon receiving the degradation determination result of YES (failure signal) from the calculation means 11D, prompts the operator to take countermeasures by generating an alarm indicating that the power module 20 is immediately (few minutes to few tens of hours) before the failure.

Note that, though the reference current ipr may be acquired from an experimental result in advance, the reference current ipr may be arbitrarily set according to the applied voltage V of the power module 20.

As described above, according to the fifth embodiment (FIGS. 9 and 14) of the present invention, the device for detecting insulation degradation of a power module includes the high-speed current detection means 25 connected to the main circuit of the power module 20, the reference frequency setting means 27 for setting the reference frequency fr, the signal processing means 26 for carrying out the signal processing using the current signal is from the high-speed current detection means 25 and the reference frequency fr as input information, and passing only the current signal ip having a frequency equal to or higher than the reference frequency fr, the reference current setting means 13D for setting the reference current ipr, the alarm means 12 to be driven by the degradation determination result of YES, and the calculation means 11D for outputting the degradation determination result of YES to the alarm means 12 only when the current signal ip exceeds the reference current ipr.

As a result, the degradation of the insulating sheet 3 can be detected in advance and a failure of the power module caused by the insulation degradation of the insulating sheet can be detected.

It is to be understood that though, in the above description, the alarm means 12 which has received the degradation determination result of YES immediately generates the alarm, the alarm may be generated at a time point when a predetermined number of the degradation determination results of YES have been received within a predetermined period.

### Sixth Embodiment

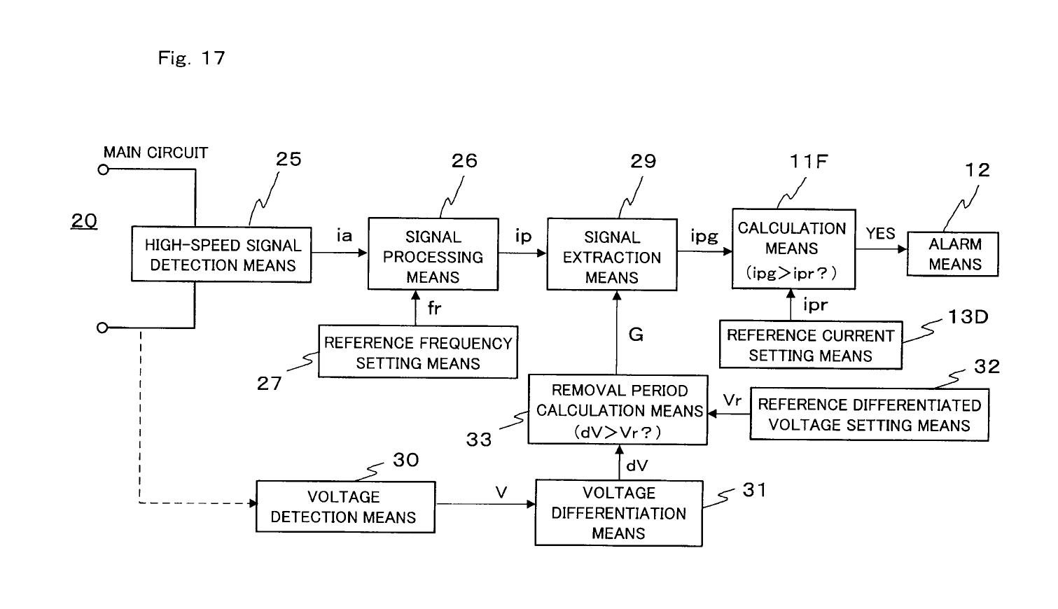

Though the current signal ip via the signal processing means 26 is compared to the reference current ipr in the calculation means 11D according to the fifth embodiment (FIG. 14) described above, as illustrated in FIG. 17, a current signal ipg obtained by removing a part of the current signal ip by signal extraction means 29 may be compared to the reference current ipr.

FIG. 17 is a block diagram for describing a method of detecting insulation degradation of a power module according to a sixth embodiment of the present invention. The like components are denoted by like symbols or by like symbols followed by “F” as those described above, and a detailed description thereof is therefore omitted.

In FIG. 17, the signal extraction means 29 is inserted between the signal processing means 26 and calculation means 11F.

Moreover, voltage detection means 30, voltage differentiation means 31, reference differentiated voltage setting means 32, and removal period calculation means 33 are provided as circuit elements relating to the calculation means 11F and the signal extraction means 29.

The voltage detection means 30 detects the applied voltage applied to the main circuit of the power module 20 as the voltage signal V, and the voltage differentiation means 31 calculates a differentiated voltage dV by differentiating the voltage signal V with respect to time (dV/dt).

The reference differentiated voltage setting means 32 sets a reference differentiated voltage dVr serving as a determination reference value in the removal period calculation means 33.

The removal period calculation means 33 carries out comparison using the differentiated voltage dV and the reference differentiated voltage dVr as input information, and generates a removal signal G only in a period Δt in which the differentiated voltage dV exceeds the reference differentiated voltage dVr.

The signal extraction means 29 carries out arithmetic processing using the current signal ip and the removal signal G as input information, removes the current signal ip during the generation period Δt of the removal signal G, and inputs a new current signal ipg to the calculation means 11F.

The calculation means 11F carries out the arithmetic processing using the reference signal ipr set by the reference current setting means 13D and the current signal ipg as input information, and outputs the degradation determination result of YES to the alarm means 12 only when the current signal ipg exceeds the reference current ipr.

The subsequent operation of the alarm means 12 is as described in the first to fourth embodiments.

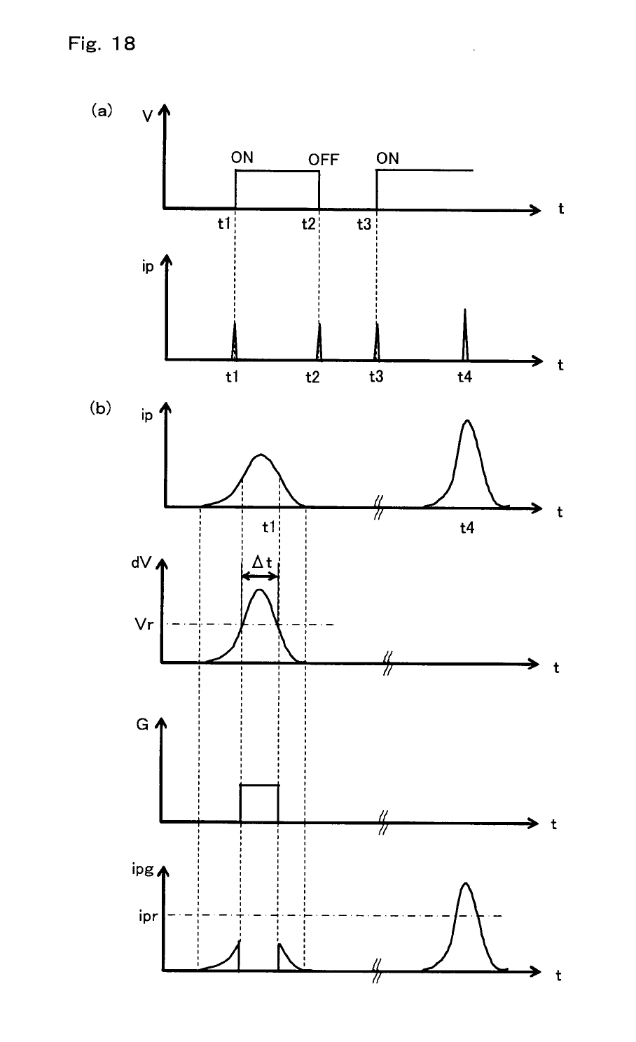

Referring to FIGS. 18(a) and 18(b), a description is now given of an operation principle of the sixth embodiment of the present invention illustrated in FIG. 17.

FIG. 18(a) is a timing chart illustrating a relationship between the voltage signal V applied to the main circuit of the power module 20 and the current signal ip from the signal processing means 26.

As illustrated in FIG. 18(a), the voltage signal V is turned on/off in response to the switching of the applied voltage at each of the times t1, t2, and t3, and a noise signal caused by this is superimposed on the current signal ip. On this occasion, the noise level is relatively high, and a difference in level from the current signal ip at the time t4 (corresponding to the degradation of the insulating sheet 3) can be very small.

As illustrated in FIG. 18(a), if the noise level is high and the comparison and determination are to be carried out by the calculation means 11D described above (FIG. 14), the noise level exceeds the reference current ipr, which can lead to a determination error.

In order to address this problem, the signal extraction means 29 is provided, and the highly reliable insulation degradation determination is realized by generating the current signal ipg as illustrated in FIG. 18(b) according to the sixth embodiment (FIG. 17) of the present invention.

FIG. 18(b) is a timing chart illustrating a relationship among the current signal ip, the differentiated voltage dV, the removal signal G, and the new current signal ipg, and illustrates an operation corresponding to the functions of the removal period calculation means 33 and the signal extraction means 29.

Note that, in FIG. 18(b), the horizontal axis (time t) is enlarged by approximately ten times compared to that of FIG. 18(a).

As illustrated in FIG. 18(b), the differentiated voltage dV having a waveform approximately the same as the current signal ip (high frequency pulse signal) and the reference differentiated voltage Vr are input to the removal period calculation means 33, and the removal period calculation means 33 generates the removal signal G only in the period Δt in which the differentiated voltage dV exceeds the reference differentiated voltage dVr.

In other words, the period Δt in which the removal signal G is generated corresponds to a period in which the noise signal is generated when the voltage signal V is turned on/off.

The signal extraction means 29 generates the new current signal ipg by removing the signal in the period Δt corresponding to the removal signal G from the current signal ip when the removal signal G is input.

As is apparent from FIG. 18(b), the new current signal ipg from the signal extraction means 29 has a waveform in which the generation period of the noise signal at the time t1 has been removed, and only the signal level at the time t4 is extracted.

The calculation means 11F can thus easily generate the highly reliable degradation determination result of YES without making a determination error.

As described above, according to the sixth embodiment (FIGS. 17 and 18) of the present invention, the device for detecting insulation degradation of a power module includes the high-speed current detection means 25 connected to the main circuit of the power module 20 for detecting the current signal ia, the reference frequency setting means 27 for setting the reference frequency fr, the signal processing means 26 for passing only the current signal ip having a frequency equal to or higher than the reference frequency fr out of the current signal ia, the voltage detection means 30 for detecting the voltage applied to the main circuit of the power module 20 as the voltage signal V, the voltage differentiation means 31 for calculating the differentiated voltage dV by differentiating the voltage signal V, the reference differentiated voltage setting means 32 for setting the reference differentiated voltage dVr, the removal period calculation means 33 for outputting the removal signal G only in the period it in which the differentiated voltage dV exceeds the reference differentiated voltage dVr, the signal extraction means 29 for removing the current signal ip in the period £t of the removal signal G, thereby outputting the new current signal ipg, the reference current setting means 13D for setting the reference current ipr, and the calculation means 11F for outputting the degradation determination result of YES to the alarm means 12 only when the current signal ipg exceeds the reference current ipr.

As a result, the degradation of the insulating sheet 3 can be detected in advance and a failure of the power module 20 caused by the insulation degradation of the insulating sheet 3 can be detected.

It is to be understood that though, in the above description, the alarm means 12 which has received the degradation determination result of YES immediately generates the alarm, the alarm may be generated at a time point when a predetermined number of the degradation determination results of YES have been received within a predetermined period.

Moreover, a method of detecting insulation degradation of a power module which provides similar operation/effect can be realized by replacing each of the means by a processing step for the device for detecting insulation degradation of a power module according to any of the first to sixth embodiments described above.

Further, any of the configurations according to the first to sixth embodiments described above can be applied to the power module system according to the present invention, and it is only necessary for the power module system to include any device for detecting insulation degradation, the semiconductor chip 1 to which the power is supplied from the main circuit of the power module 20, the heat spreader 2 on which the semiconductor chip 1 is mounted, and the insulating sheet 3 placed on the rear surface of the heat spreader 2.

### REFERENCE SIGNS LIST

1 semiconductor chip, 2 heat spreader, 3 insulating sheet, 7 epoxy resin, 10 current detection means, 11, 11A, 11B, 11C, 11D, 11F, 11H calculation means, 12 alarm means, 13, 13D reference current setting means, 14 current storage means, 15 current differentiation means, 20 power module, 21 antenna, 22 reference signal setting means, 23 switching signal removing means, 25 switching signal removing means, 26 signal processing means, 27 reference frequency setting means, 29 signal extraction means, 30 voltage detection means, voltage differentiation means, 32 reference differentiated voltage setting means, 33 removal period calculation means, di differentiated current, dir reference differentiated current, dV differentiated voltage, dVr reference differentiated voltage, Epower supply, fr reference frequency, G removal signal, i current value, ia, ip, ipg current signal, in present current value, i(n−1) previous current value, ir, ipr reference current, Sa electromagnetic wave signal, Sb electromagnetic wave signal, Sr reference signal, V voltage signal (voltage applied to power module), Vr reference differentiated voltage, YES degradation determination result, Δt period of removal signal

1-14. (canceled)

15. A power module, in which heat is discharged to an outside via an insulating sheet of a resin layer, and which is sealed by a resin, comprising:
current detection means for sampling and detecting a current value flowing through the insulating sheet at a predetermined time interval;
calculation means for determining, using the current value, a state in which an insulation characteristic of the insulating sheet is so degraded that breakdown is imminent based on a characteristic of a current change immediately before dielectric breakdown in a precursory period until the dielectric breakdown, and outputting a degradation determination result when the calculation means determines that the insulating sheet is in the state immediately before the breakdown;
current storage means for storing a current value at a previous sampling time point; and
alarm means for generating an alarm in response to the degradation determination result.

16. A power module according to claim 15, wherein the characteristic of the current change immediately before the dielectric breakdown in the precursory period until the dielectric breakdown is that a current value at a present sampling time point exceeds ten times the current value at the previous sampling time point.

17. A power module according to claim 15, further comprising current differentiation means for calculating a differentiated current by differentiating the current value,
wherein the characteristic of the current change immediately before the dielectric breakdown in the precursory period until the dielectric breakdown is that a value of the differentiated current at the sampling time point exceeds a predetermined value.

18. A power module according to claim 15, wherein the characteristic of the current change immediately before the dielectric breakdown in the precursory period until the dielectric breakdown is that a current pulse is detected several times or more immediately before the breakdown of the insulating sheet.

19. A power module according to claim 15, wherein the resin sealing the insulating sheet is one of an epoxy resin and a silicone gel.

20. A power module according to claim 15, further comprising:
an antenna for detecting an electromagnetic signal emitted from the power module; and
reference signal setting means for setting a reference signal which serves as a degradation determination reference value indicating degradation of the insulating sheet,
wherein the calculation means outputs the degradation determination result when the electromagnetic signal exceeds the reference signal.

21. A power module according to claim 20, wherein the calculation means outputs the degradation determination result when the reference signal is exceeded by an electromagnetic signal obtained by removing a noise signal, which is generated due to turning on/off of a circuit voltage and is irrelevant to the degradation of the insulating sheet, from the electromagnetic signal detected by the antenna.

22. A power module according to claim 15, further comprising:
high-speed current detection means connected to a main circuit of the power module;
reference frequency setting means for setting a reference frequency;
signal processing means for passing only a current signal ip having a frequency equal to or higher than the reference frequency; and
reference current setting means for setting a reference current ipr,
wherein the calculation means carries out arithmetic processing using the current signal ip and the reference current ipr as input information, and outputs the degradation determination result only when the current signal ip exceeds the reference current ipr.

23. A power module according to claim 17, wherein:
the calculation means comprises:
voltage detection means for detecting a voltage signal applied to the main circuit of the power module; and
reference differentiated voltage setting means for setting a reference differentiated voltage; and
the calculation means is configured to:
obtain a new current signal ipg by removing the current signal ip obtained from the signal processing means only in a period Δt in which the differentiated voltage exceeds the reference differentiated voltage; and
carry out arithmetic processing for the current signal ipg and the reference current ipr, and output the degradation determination result to the alarm means only when the current signal ipg exceeds the reference current ipr.

24. A power module according to claim 15, wherein the alarm is generated at a time point when the degradation determination result is received a predetermined number of times.

25. A power module according to claim 15, further comprising:
a semiconductor chip to be supplied with power by a main circuit of the power module;
a heat spreader on which the semiconductor chip is mounted; and
a foil disposed in close contact with a rear surface of the heat spreader through an intermediation of the insulating sheet.

26. A method of detecting insulation degradation of a power module in which heat is discharged to an outside via an insulating sheet of a resin layer, and which is sealed by a resin, comprising:
a current detection step of sampling and detecting a current value flowing through the insulating sheet;
a calculation step of determining, using the current value, a state in which an insulation characteristic of the insulating sheet is so degraded that breakdown is imminent based on a characteristic of a current change immediately before dielectric breakdown in a precursory period until the dielectric breakdown, and outputting a degradation determination result when the insulating sheet is in the state immediately before the breakdown;
a current storing step of storing the current value at a previous sampling time point; and
an alarm step of generating an alarm in response to the degradation determination result.

27. A method of detecting insulation degradation of a power module according to claim 26, wherein the characteristic of the current change immediately before the dielectric breakdown in the precursory period until the dielectric breakdown is that a current value at a present sampling time point exceeds ten times the current value at the previous sampling time point.

28. A method of detecting insulation degradation of a power module according to claim 26, further comprising a differentiation step of calculating a differentiated current by differentiating the current value,
wherein the characteristic of the current change immediately before the dielectric breakdown in the precursory period until the dielectric breakdown is that the value of the differentiated current at a sampling time point exceeds a predetermined value.

29. A method of detecting insulation degradation of a power module according to claim 26, wherein the characteristic of the current change immediately before the dielectric breakdown in the precursory period until the dielectric breakdown is that a current pulse is detected several times or more immediately before the breakdown of the insulating sheet.
